(19) United States
(12) Patent Application Publication
(10) Pub. No.: US 2022/0200295 A1
(43) Pub. Date: Jun. 23, 2022

(54) SYSTEMS AND METHOD FOR CHARGING BATTERIES

(71) Applicant: Medtronic, Inc., Minneapolis, MN (US)

(72) Inventors: Hui Ye, Maple Grove, MN (US); Prabhakar A. Tamirisa, Brooklyn Park, MN (US)

(21) Appl. No.: 17/133,500

(22) Filed: Dec. 23, 2020

(51) Int. Cl. H02J 7/00; H01M 10/44; H01M 10/46; H01M 10/48; H01M 10/42; H01M 10/0525; G01R 31/392; G01R 31/389

(52) U.S. Cl. CPC H02J 7/0013; H02J 7/005; H02J 7/007; H01M 10/441; H01M 10/46; H01M 2010/4271; H01M 10/4257; H01M 10/0525; G01R 31/392; G01R 31/389; H01M 10/482

(57) ABSTRACT

A charging voltage of a battery may be determined based on an age of the battery. The age and charging voltage can be determined by a computing apparatus or a battery management system. The determined charging voltage may increase as the age of the battery increases. The battery may be charged at the charging voltage for the duration of a charge cycle. The battery may be charged using a charger.

### FIELD

The present disclosure relates to, among other things, rechargeable batteries or electrochemical cells.

### TECHNICAL BACKGROUND

Rechargeable batteries or electrochemical cells (i.e., rechargeable or “secondary” batteries) include one or more positive electrodes, one or more negative electrodes, and an electrolyte provided within a case or housing. Separators made from a porous polymer or other suitable material may also be provided intermediate or between the positive and negative electrodes to prevent direct contact between adjacent electrodes. The positive electrode includes a current collector having an active material provided thereon, and the negative electrode includes a current collector having an active material provided thereon.

Rechargeable lithium ion batteries are the primary power source for many portable electronic devices and electrical vehicles. It can be challenging to recharge a lithium ion battery quickly without damaging the battery or creating a hazard. Limitations to recharge lithium ion batteries can include a kinetic limitation and a thermodynamic limitation. The kinetic limitation relates to battery impedance. Battery impedance can lead to overheating or lithium plating with a sufficiently high charging current. Keeping the charging current low enough to prevent lithium plating may result in lengthy charging times for batteries. The thermodynamic limitation is related to a charging cutoff voltage. High cell voltage may speed up cathode degradation and electrolyte oxidation which can accelerate capacity degradation of the battery. Accordingly, an upper charge cutoff voltage and a charge current rate may be chosen to strike a balance between a battery charge time and a usable life of the battery. A lower charge cutoff voltage can extend the battery life but may decrease a useable capacity of the battery. A lower charge current may cause lengthy charging times of the battery that may not be favorable for a user. Additionally, such charging times may further increase as the battery ages because battery resistance typically grows as the battery ages. As a result, recharge capabilities of rechargeable lithium ion batteries may decrease as the battery ages.

Such issues tend to arise when the negative active material is, for example, graphite or silicon, which have an electrode potential similar to lithium metal. In such batteries, the cell capacity is typically limited by the positive electrode. Thus, increasing charging voltage of the cell will increase the positive electrode potential and lead to increased cell performance degradation.

### BRIEF SUMMARY

As described herein, constant fast recharging can be achieved using a rechargeable lithium ion battery with its capacity limited by the negative electrode. Batteries with their charging capacity limited by the negative electrode may include negative materials having a lithium ion intercalation potential at least 0.5 Volts above lithium metal. Lithium ion batteries with their charging capacities limited by their negative electrodes may prevent lithium ion plating during fast recharge. In addition, lithium ion batteries having their charge capacities limited by the negative electrode may prevent positive electrode potentials from increasing as the charge cutoff voltage is increased, and thus the performance stability of the cell may not be impacted. As such, charging voltage for recharging such batteries may be large at the outset to permit fast recharge and may be increased as the battery ages to maintain similar charging times without substantial performance degradation.

Described herein, among other things, is a battery charging apparatus configured to charge a battery at a charging voltage based on a determined an age of a battery. By increasing the charging voltage as the battery ages, the apparatus may prevent charge time of the battery from increasing as the battery ages and impedance of the battery grows. The battery may be a lithium ion battery comprising an anode having a lithium ion intercalation potential of at least 0.5 V above lithium metal.

In general, in one aspect, the present disclosure describes a method comprising determining an age of a battery, determining a charging voltage for charging the battery, wherein the charging voltage increases as the age of the battery increases, and charging the battery at the charging voltage for the duration of a charge cycle.

In embodiments, determining the charging voltage may comprises determining a base charging voltage, determining a charging voltage increase based on the determined age of the battery and summing the base charging voltage and the charging voltage increase.

In embodiments, determining the age of the battery may comprise determining a number of cycles the battery has been charged. In embodiments, determining the age of the battery comprises determining an internal impedance of the battery. In embodiments, determining the age of the battery may comprises supplying a test current to the battery, and determining a test voltage while the test current is supplied. In embodiments, determining the age of the battery may comprise determining a time period between a first charge cycle of the battery and a current charge cycle of the battery.

In embodiments, determining the charging voltage for charging the battery is further based on a charging time threshold. In embodiments, determining the charging voltage for charging the battery may be further based on a turbo charge setting, wherein the turbo charge setting is adjustable by a user.

In general, in another aspect, the present disclosure describes a battery charging apparatus comprising a charger to charge one or more batteries and a computing apparatus. The computing apparatus comprises one or more processors operably coupled to the charger and configured to determine an age of a battery, determine a charging voltage for charging the battery based on the determined age of the battery, wherein the charging voltage increases as the age of the battery increases, and cause the charger to charge the battery at the charging voltage for the duration of a charge cycle.

In embodiments, to determine the charging voltage the computing apparatus may be configured to determine a base charging voltage, determine a charging voltage increase based on the determined age of the battery, and sum the base charging voltage and the charging voltage increase.

In embodiments, to determine the age of the battery, the computing apparatus may be configured to determine a number of times the battery has been charged. In embodiments, to determine the age of the battery, the computing apparatus may be configured to determine an internal impedance of the battery. In embodiments, to determine the age of the battery, the computing apparatus may be configured to supply a test voltage to the battery and determine a test current while the test voltage is supplied.

In embodiments, to determine the age of the battery, the computing apparatus may be configured to determine a time period between a first charge cycle of the battery and a current charge cycle of the battery.

In embodiments, the computing apparatus may be configured to determine the charging voltage based on the determined age of the battery and a charging time threshold. In embodiments, the computing apparatus may be configured to determine the charging voltage based on the determined age of the battery and a turbo charge setting, wherein the turbo charge setting is adjustable by a user.

In embodiments, the battery may be a lithium ion battery, wherein the battery comprises an anode having a lithium ion intercalation potential of at least 0.5 V above lithium metal.

In general, in another aspect, the present disclosure describes a system comprising a charging apparatus for charging one or more batteries and a battery operatively coupled to the charging apparatus. The battery comprises one or more electrochemical cells and a battery management system. The battery management system comprises one or more processors operably coupled to the one or more electrochemical cells. The battery management system is configured to determine an age of the battery, determine a charging voltage for charging the battery based on the determined age of the battery, wherein the charging voltage increases as the age of the battery increases, and cause the charger to charge the battery at the charging voltage for the duration of a charge cycle.

In embodiments, to determine the charging voltage, the battery management system may be configured to determine a base charging voltage, determine a charging voltage increase based on the determined age of the battery, and sum the base charging voltage and the charging voltage increase.

In embodiments, to determine the age of the battery, the battery management system may be configured to determine a number of times the battery has been charged. In embodiments, to determine the age of the battery, the battery management system may be configured to determine an internal impedance of the battery. In embodiments, to determine the age of the battery, the battery management system may be configured to supply a test current to the battery and determine a test voltage while the test current is supplied. In embodiments, to determine the age of the battery, the battery management system may be configured to determine a time period between a first charge cycle of the battery and a current charge cycle of the battery.

In embodiments, the battery may be disposed in a device. In embodiments, the battery may be a lithium ion battery, wherein the battery comprises an anode having a lithium ion intercalation potential of at least 0.5 V above lithium metal.

Advantages and additional features of the subject matter of the present disclosure will be set forth in the detailed description which follows, and in part will be readily apparent to those skilled in the art from that description or recognized by practicing the subject matter of the present disclosure as described herein, including the detailed description which follows, the claims, as well as the appended drawings.

It is to be understood that both the foregoing general description and the following detailed description present embodiments of the subject matter of the present disclosure, and are intended to provide an overview or framework for understanding the nature and character of the subject matter of the present disclosure as it is claimed. The accompanying drawings are included to provide a further understanding of the subject matter of the present disclosure and are incorporated into and constitute a part of this specification. The drawings illustrate various embodiments of the subject matter of the present disclosure and together with the description serve to explain the principles and operations of the subject matter of the present disclosure. Additionally, the drawings and descriptions are meant to be merely illustrative and are not intended to limit the scope of the claims in any manner.

### BRIEF DESCRIPTION OF THE DRAWINGS

The following detailed description of specific embodiments of the present disclosure can be best understood when read in conjunction with the following drawings, in which:

FIG. 1 is a schematic block diagram of an embodiment of a battery charging apparatus and a device;

FIG. 2 is a schematic block diagram of an embodiment of a battery charging apparatus;

FIG. 3 is a schematic representation of an embodiment of a portion of a rechargeable battery;

FIG. 4 is a schematic cross-sectional view of a portion of a battery or electrochemical cell according to an exemplary embodiment that includes at least one positive electrode and at least one negative electrode;

FIG. 5 is a flow diagram of an embodiment of a process for determining a charging voltage of a battery; and

The schematic drawing is not necessarily to scale.

### DETAILED DESCRIPTION

Reference will now be made in greater detail to various embodiments of the subject matter of the present disclosure, some embodiments of which are illustrated in the accompanying drawings. Like numbers used in the figures refer to like components and steps. However, it will be understood that the use of a number to refer to a component in a given figure is not intended to limit the component in another figure labeled with the same number. In addition, the use of different numbers to refer to components in different figures is not intended to indicate that the different numbered components cannot be the same or similar to other numbered components.

Constant fast recharging can be achieved using a rechargeable lithium ion battery with its capacity limited by negative electrode using negative materials with a lithium ion intercalation potential at least 0.5 Volts above lithium metal. Additionally, a regulated constant voltage charge algorithm can be applied to charge such a battery where the charge voltage is increased over time to offset the battery impedance growth. Negative materials with a lithium ion intercalation potential at least 0.5 Volts (V) above lithium metal may include Zr, Ti, Nb, W, V oxide, or compounds that can function as a host of lithium ion. Such negative materials may include, for example, zirconium dioxide (ZrO₂), titanium dioxide (TiO₂), niobium pentoxide (Nb₂O₅), tungsten trioxide (WO₇), vanadium pentoxide (V₂O₅), lithium titanate (Li₄Ti₅O₁₂), TiNb₂O₇, Ti₂Nb₂O₉, Ti₂Nb₁₀O₂₉, TiNb₆O₁₇, TiNb₁₄O₃₇, TiNb₂₄O₆₂, Nb₁₆W₅O₅₅, and Nb₁₈W₁₆O₉₃, and so on.

Negative material with electrode potential>0.5 volts above lithium metal and a cell design with its capacity limited by the negative electrode are factors that allows for increasing charging voltage overtime without long-term performance impact.

Using negative materials with lithium ion interaction potential of at least 0.5 V in battery anodes may reduce or prevent lithium plating during fast recharge. Typically, higher charging voltages (e.g., faster charging times) may result in increased lithium plating for Li ion batteries using graphite based negative materials. Lithium plating may reduce battery capacity and cause short circuits. Reducing or preventing lithium plating may allow for higher charging voltages, even as the battery ages. Accordingly, charging voltages can be increased as a battery ages. Furthermore, constant voltage recharging can be used. Constant voltage recharging as described herein can result in shorter recharge times when compared to conventional constant current/constant voltage charging. Negative electrode capacity limited battery designs and designs with anodes with lithium ion interaction potential of at least 0.5 V may enable stable positive electrode potential when battery charge voltage is increased as the battery ages. Thus, as the battery charge voltage is increased as the battery ages, the increased charging voltage may not substantially increase battery degradation.

As used herein “constant voltage charging” refers to charging a battery at a consistent voltage (e.g., a voltage deviation of less than plus or minus 0.025 V) for the duration of a charge cycle. In contrast, other charging methods do not maintain a consistent voltage throughout a charge cycle. For example, with constant current/constant voltage charging, the charger limits the amount of current to a pre-set level until the battery reaches a pre-set voltage level. The current then reduces as the battery becomes fully charged.

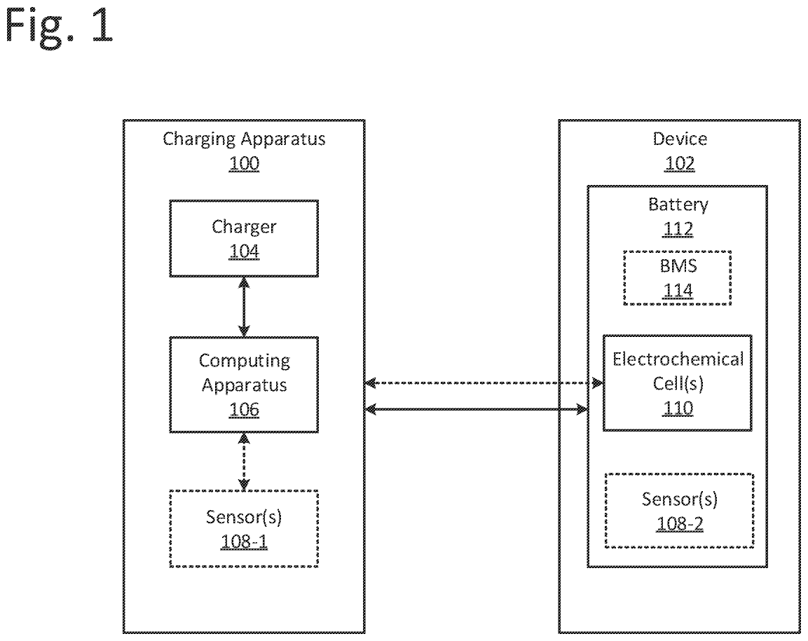

Referring now to FIG. 1, a schematic block diagram of a charging apparatus 100 and a device 102 is shown.

The charging apparatus 100 includes a charger 104 and a computing apparatus 106. The charging apparatus 100 may optionally include one or more sensors 108-1. The charging apparatus 100 may include a housing (not shown) to house the charger 104 and the computing apparatus 106. The housing may also house the sensors 108-1.

The device 102 includes battery 112. Although only shown with a single battery (e.g., battery 112), the device may include multiple batteries. The battery 112 may include one or more electrochemical cells 110, a battery management system (BMS) 114, and one or more sensors 108-2. The device 102 may be a medical device. The medical device may be, for example, an implantable neurostimulator, ventilator, surgical stapler, or medical monitoring equipment.

The charger 104 may be configured to charge the battery 112. Although only one battery is shown, the charger 104 may be configured to charge multiple batteries. The charger 104 may include any suitable circuitry or electronics to charge the battery 112 such as, e.g., a power source, rectifier circuit, power circuit, control circuit, regulator circuit, fault detection circuit, etc.

The computing apparatus 106 may be operatively coupled to the charger 104. The computing apparatus 106 may control the charger 104 to charge the battery 112. The computing apparatus 106 may be operatively coupled to the sensors 108-1. The computing apparatus may be configured to monitor various conditions related to charging the battery 112 or the electrochemical cells 110 such as, e.g., charging current, voltage, temperature, etc. Additionally, the computing apparatus 106 may be configured to determine an age of the battery 112, determine a charging voltage of the battery, and cause the charger to charge the battery according to the various methods described herein.

The age of the battery 112 may be determined in any suitable manner. The age of the battery 112 may be determined directly or indirectly. The age of the battery may relate to the passage of time since the manufacture of the battery, may reflect deteriorating performance associated with use or charging of the battery, or the like. The determination of the age of the battery may be an estimate of battery age based on one or more parameters indicative of battery aging. For example, the age of the battery 112 may be determined based on the number of times the battery has been charged, with each charging increasing the determined age of the battery; based on a time period between a first charge cycle and a current charge cycle, with a longer time period increasing the determined age of the battery; based on internal impedance, with increased internal impedance increasing the determined age of the battery, and the like.

Data regarding the age of the battery 112 may be stored in the BMS 114, obtained by sensor(s) 108-1, 108-2, or the like. Data regarding the age of the battery 112 may be provided to the computing apparatus 106 so that computing apparatus 106 may determine the age of the battery 112 based on the data.

In one embodiment, to determine the age of the battery the computing apparatus 106 may be configured to determine a number of times the battery has been charged. The number of times the battery has been charged may be stored in the BMS 114 and provided to the computing apparatus 106. In one embodiment, to determine the age of the battery the computing apparatus 106 may be configured to determine a time period between a first charge cycle of the battery and a current charge cycle of the battery. The time of the first charge cycle may be stored in the BMS 114 and provided to the computing apparatus 106.

In one embodiment, to determine the age of the battery the computing apparatus 106 may be configured to determine an internal impedance of the battery. For example, the computing apparatus 106 may be configured to cause the charger 104 to supply a test current to the battery and determine a test voltage while the test current is supplied. The test voltage may be obtained by sensor(s) 108-1, 108-2. The computing apparatus 106 may determine the internal impedance of the battery based on the test voltage and the test current using, for example, Ohm's law, a table of values, etc.

The computing apparatus 106 may be configured to determine a charging voltage for charging the battery 112 based on the determined age of the battery. The determined charging voltage may increase as the age of the battery increases. In one embodiment, to determine the charging voltage the computing apparatus 106 may be configured to determine a base charging voltage and a charging voltage increase based on the determined age of the battery 112. Additionally, the computing apparatus 106 may be configured to sum the base charging voltage and the charging voltage increase. Accordingly, the determined charging voltage may be equal to the sum of the determined base charging voltage and the determined charging voltage increase.

If the magnitude of the age of the battery 106 is determined to be small (e.g., the battery is new or “young”), the charging voltage may be smaller than if the battery 106 is determined to be old.

In one embodiment, the computing apparatus 106 may be configured to determine a charging voltage for charging the battery 112 based on the determined age of the battery and a charging time threshold. In other words, the computing apparatus 106 may determine a charging voltage for charging the battery 112 that will charge the battery within a time period equal to or less than the charging time threshold. The charging time threshold may be equal to or less than 1 hour, preferably equal to or less than 30 minutes, or more preferably equal to or less than 20 minutes.

In one embodiment, the computing apparatus 106 may be configured to determine a charging voltage for charging the battery 112 based on the determined age of the battery and a turbo charge setting. The turbo charge setting may be adjustable by a user. In other words, the computing apparatus 106 may be configured to increase the charging voltage to decrease the charging time (e.g., duration) of a charge cycle of the battery 112 below a default charging time.

The battery 112 may include a plurality of electrochemical cells 110. The electrochemical cells 110 can be arranged in parallel, series, or a combination thereof. The electrochemical cells 110 may be lithium ion electrochemical cells. The electrochemical cells 110 are rechargeable electrochemical cells. The electrochemical cells 110 may have any suitable voltage, capacity, supply current, etc. The electrochemical cells 110 may be incorporated into a battery 112.

In one embodiment, the battery 112 is a lithium ion battery. The battery 112 may include an anode having a lithium ion intercalation potential greater than that of lithium metal. The anode of the battery 112 may have a lithium ion intercalation potential of at least 0.5 Volts (V) above lithium metal.

The battery 112 may include the BMS 114 to monitor the electrochemical cells 110, maintain safe operating conditions of the electrochemical cells, report various conditions of the electrochemical cells, Additionally, the BMS 114 may be configured to determine an age of the battery 112, determine a charging voltage of the battery, and cause the charger to charge the battery according to the various methods described herein. That is, the BMS 114 may comprise computing apparatus (not shown) to carry out one or more aspects described herein regarding computing apparatus 106.

In one embodiment, to determine the age of the battery the BMS 114 may be configured to determine a number of times the battery has been charged. In one embodiment, to determine the age of the battery the BMS 114 may be configured to determine a time period between a first charge cycle of the battery and a current charge cycle of the battery.

In one embodiment, to determine the age of the battery the BMS 114 may be configured to determine an internal impedance of the battery. For example, the computing apparatus 106 may be configured to cause the charger 104 to supply a test current to the battery, and the BMS 114 may determine a test voltage while the test current is supplied. The internal impedance of the battery may be determined based on the test voltage and the test current using, for example, Ohm's law, a table of values, etc.

The BMS 114 may be configured to determine a charging voltage for charging the battery 112 based on the determined age of the battery. The determined charging voltage may increase as the age of the battery increases. In one embodiment, to determine the charging voltage the BMS 114 may be configured to determine a base charging voltage and a charging voltage increase based on the determined age of the battery 112. Additionally, the BMS 114 may be configured to sum the base charging voltage and the charging voltage increase. Accordingly, the determined charging voltage may be equal to the sum of the determined base charging voltage and the determined charging voltage increase.

In one embodiment, the BMS 114 may be configured to determine a charging voltage for charging the battery 112 based on the determined age of the battery and a charging time threshold. In other words, the BMS 114 may determine a charging voltage for charging the battery 112 that will charge the battery within a time period equal to or less than the charging time threshold. The charging time threshold may be equal to or less than 1 hour, preferably equal to or less than 30 minutes, or more preferably equal to or less than 20 minutes.

In one embodiment, the BMS 114 may be configured to determine a charging voltage for charging the battery 112 based on the determined age of the battery and a turbo charge setting. The turbo charge setting may be adjustable by a user. In other words, the BMS 114 may be configured to increase the charging voltage to decrease the charging time (e.g., duration) of a charge cycle of the battery 112 below a default charging time.

The battery 112 may further include sensors 108-2 to sense temperature, voltage, current, etc. The sensors 108-1, 108-2 (referred to collectively as sensors 108) may include any suitable sensor or sensors such as, e.g., temperature sensors, current sensors, voltage sensors, state of charge sensors, etc. The sensors 108 may provide a sensed temperature signal, sensed current signal, sensed voltage signal, sensed state of charge signal, etc. The signals provided by the sensors 108 may be indicative of the properties sensed by the sensors.

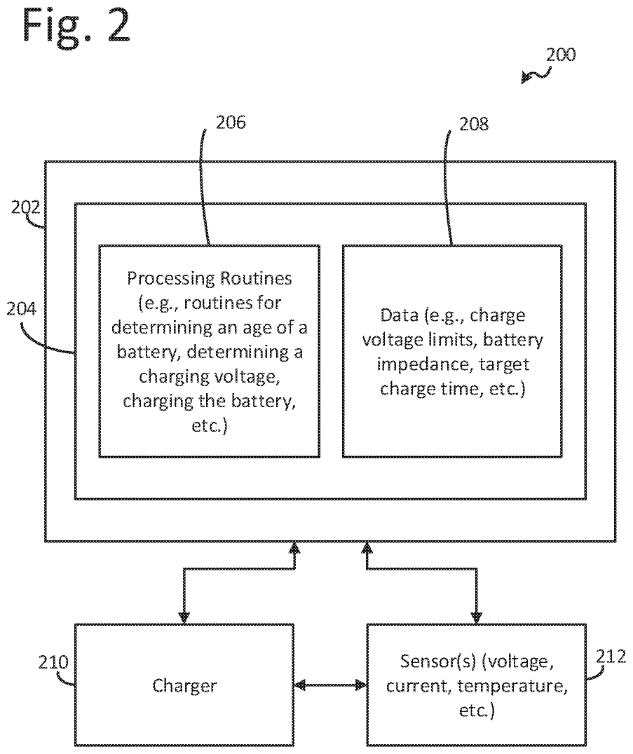

Referring now to FIG. 2, a schematic block diagram of a charging apparatus 200 (e.g., charging apparatus 100 of FIG. 1) according to embodiments described herein is shown. The charging apparatus 200 may include a computing apparatus or processor 202 and a charger 210. Generally, the charger 210 may be operably coupled to the computing apparatus 202 and may include any suitable circuits or devices configured charge batteries or electrochemical cells. For example, the charger 210 may include one or more power sources, rectifier circuits, power circuits, control circuits, regulator circuits, fault detection circuits, etc.

The charging apparatus 200 may additionally include one or more sensors 212 operably coupled to the computing apparatus 202. Generally, the sensors 212 may include any one or more devices configured to sense charging information of the charger 210 or electrochemical cells. The sensors 212 may include any apparatus, structure, or device to capture the charging information of the charger such as one or more current sensors, voltage sensors, temperature sensors, etc.

Further, the computing apparatus 202 includes data storage 204. Data storage 204 allows for access to processing programs or routines 206 and one or more other types of data 208 that may be employed to carry out the techniques, processes, and algorithms of determining a health of an electrochemical cell. For example, processing programs or routines 206 may include programs or routines for determining an age of a battery, determining a charging voltage, charging a battery, determining a state of health of a battery, computational mathematics, matrix mathematics, Fourier transforms, compression algorithms, calibration algorithms, image construction algorithms, inversion algorithms, signal processing algorithms, normalizing algorithms, deconvolution algorithms, averaging algorithms, standardization algorithms, comparison algorithms, vector mathematics, or any other processing required to implement one or more embodiments as described herein.

Data 208 may include, for example, charging voltage data, battery age data, temperature data, voltage data, charging current data, state of health data, state of charge data, thresholds, arrays, meshes, grids, variables, counters, statistical estimations of accuracy of results, results from one or more processing programs or routines employed according to the disclosure herein (e.g., determining an age of a battery, determining a charging voltage of a battery, etc.), or any other data that may be necessary for carrying out the one or more processes or techniques described herein.

In one or more embodiments, the charging apparatus 200 may be controlled using one or more computer programs executed on programmable computers, such as computers that include, for example, processing capabilities (e.g., microcontrollers, programmable logic devices, etc.), data storage (e.g., volatile or non-volatile memory and/or storage elements), input devices, and output devices. Program code and/or logic described herein may be applied to input data to perform functionality described herein and generate desired output information. The output information may be applied as input to one or more other devices and/or processes as described herein or as would be applied in a known fashion.

The programs used to implement the processes described herein may be provided using any programmable language, e.g., a high-level procedural and/or object orientated programming language that is suitable for communicating with a computer system. Any such programs may, for example, be stored on any suitable device, e.g., a storage media, readable by a general or special purpose program, computer or a processor apparatus for configuring and operating the computer when the suitable device is read for performing the procedures described herein. In other words, at least in one embodiment, the charging apparatus 200 may be controlled using a computer readable storage medium, configured with a computer program, where the storage medium so configured causes the computer to operate in a specific and predefined manner to perform functions described herein.

The computing apparatus 202 may be, for example, any fixed or mobile computer system (e.g., a personal computer or minicomputer). The exact configuration of the computing apparatus is not limiting and essentially any device capable of providing suitable computing capabilities and control capabilities (e.g., control the sound output of the charging apparatus 200, the acquisition of data, such as image data, audio data, or sensor data) may be used. Additionally, the computing apparatus 202 may be incorporated in a housing of the charging apparatus 200. Further, various peripheral devices, such as a computer display, mouse, keyboard, memory, printer, scanner, etc. are contemplated to be used in combination with the computing apparatus 202. Further, in one or more embodiments, the data 208 (e.g., image data, sound data, voice data, audio classes, audio objects, optical components, hearing impairment settings, hearing device settings, an array, a mesh, a digital file, etc.) may be analyzed by a user, used by another machine that provides output based thereon, etc. As described herein, a digital file may be any medium (e.g., volatile or non-volatile memory, a CD-ROM, a punch card, magnetic recordable tape, etc.) containing digital bits (e.g., encoded in binary, trinary, etc.) that may be readable and/or writeable by computing apparatus 202 described herein. Also, as described herein, a file in user-readable format may be any representation of data (e.g., ASCII text, binary numbers, hexadecimal numbers, decimal numbers, audio, graphical) presentable on any medium (e.g., paper, a display, sound waves, etc.) readable and/or understandable by a user.

In view of the above, it will be readily apparent that the functionality as described in one or more embodiments according to the present disclosure may be implemented in any manner as would be known to one skilled in the art. As such, the computer language, the computer system, or any other software/hardware that is to be used to implement the processes described herein shall not be limiting on the scope of the systems, processes or programs (e.g., the functionality provided by such systems, processes or programs) described herein.

The techniques described in this disclosure, including those attributed to the systems, or various constituent components, may be implemented, at least in part, in hardware, software, firmware, or any combination thereof. For example, various aspects of the techniques may be implemented by the computing apparatus 202, which may use one or more processors such as, e.g., one or more microprocessors, DSPs, ASICs, FPGAs, CPLDs, microcontrollers, or any other equivalent integrated or discrete logic circuitry, as well as any combinations of such components, image processing devices, or other devices. The term “processing apparatus,” “processor,” or “processing circuitry” may generally refer to any of the foregoing logic circuitry, alone or in combination with other logic circuitry, or any other equivalent circuitry. Additionally, the use of the word “processor” may not be limited to the use of a single processor but is intended to connote that at least one processor may be used to perform the techniques and processes described herein.

Such hardware, software, and/or firmware may be implemented within the same device or within separate devices to support the various operations and functions described in this disclosure. In addition, any of the described components may be implemented together or separately as discrete but interoperable logic devices. Depiction of different features, e.g., using block diagrams, etc., is intended to highlight different functional aspects and does not necessarily imply that such features must be realized by separate hardware or software components. Rather, functionality may be performed by separate hardware or software components or integrated within common or separate hardware or software components.

When implemented in software, the functionality ascribed to the systems, devices and techniques described in this disclosure may be embodied as instructions on a computer-readable medium such as RAM, ROM, NVRAM, EEPROM, FLASH memory, magnetic data storage media, optical data storage media, or the like. The instructions may be executed by the computing apparatus 202 to support one or more aspects of the functionality described in this disclosure.

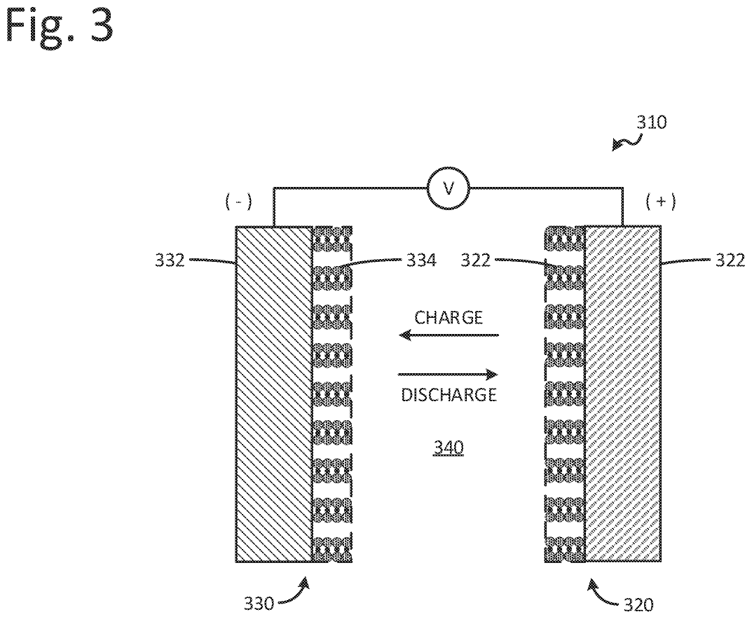

Referring now to FIG. 3 a schematic representation of a portion of a lithium-ion battery 310 is shown (e.g., battery 112 of FIG. 1). The battery 310 includes a positive electrode 320 that includes a positive current collector 322 and a positive active material 324, a negative electrode 330 that includes a negative current collector 332 and a negative active material 334, an electrolyte material 340, and a separator (e.g., a polymeric microporous separator, not shown) provided intermediate or between the positive electrode 320 and the negative electrode 330. The electrodes 320, 330 may be provided as relatively flat or planar plates or may be wrapped or wound in a spiral or other configuration (e.g., an oval configuration). The electrode may also be provided in a folded configuration.

During charging and discharging of the battery 310, lithium ions move between the positive electrode 320 and the negative electrode 330. For example, when the battery 310 is discharged, lithium ions flow from the negative electrode 330 to the positive electrode 320. In contrast, when the battery 310 is charged, lithium ions flow from the positive electrode 320 to the negative electrode 330.

Once assembly of the battery is complete, an initial charging operation (referred to as a “formation process”) may be performed. During this process, a stable Solid-electrolyte inter-phase (SEI) layer is formed at the negative electrode and also possibly at the positive electrode. These SEI layers act to passivate the electrode-electrolyte interfaces as well as to prevent side-reactions thereafter.

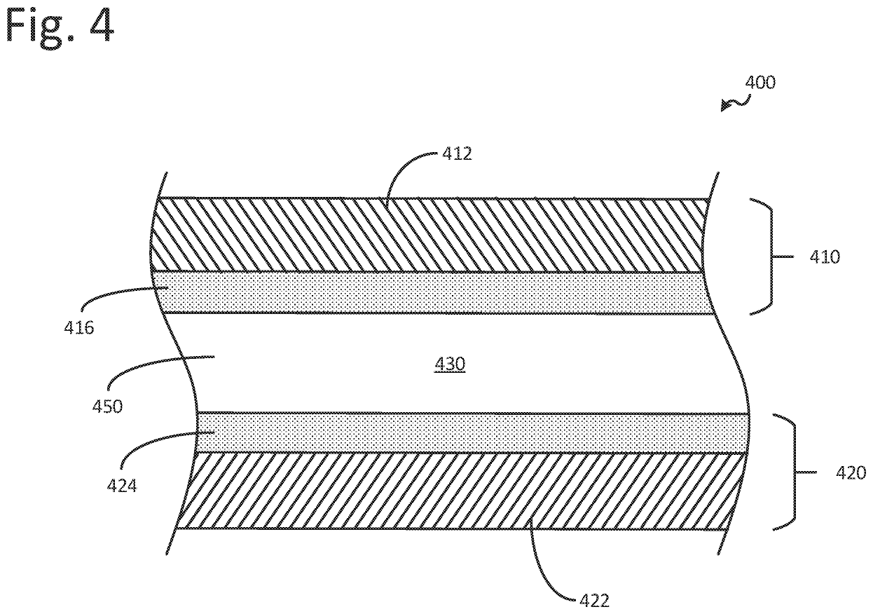

FIG. 4 is a schematic cross-sectional view of a portion of a battery or electrochemical cell 400 (e.g., battery 112 or electrochemical cell(s) 110 of FIG. 1) according to an exemplary embodiment that includes at least one positive electrode 410 and at least one negative electrode 420. The size, shape, and configuration of the battery may be selected based on the desired application or other considerations. For example, the electrodes may be flat plate electrodes, wound electrodes (e.g., in a jellyroll, folded, or other configuration), or folded electrodes (e.g., Z-fold electrodes). According to other exemplary embodiments, the battery may be a button electrochemical battery, a thin film solid state battery, or another type of lithium-ion battery.

The battery case or housing (not shown) is formed of a metal or metal alloy Such as aluminum or alloys thereof, titanium or alloys thereof, stainless steel, or other suitable materials. According to another exemplary embodiment, the battery case may be made of a plastic material or a plastic-foil laminate material (e.g., an aluminum foil provided intermediate a polyolefin layer and a nylon or polyester layer).

An electrolyte is provided intermediate or between the positive and negative electrodes to provide a medium through which lithium ions may travel. According to an exemplary embodiment, the electrolyte may be a liquid (e.g., a lithium salt dissolved in one or more non-aqueous solvents). According to an exemplary embodiment, the electrolyte may be a mixture of ethylene carbonate (EC), ethylmethyl carbonate (EMC) and a 1.0 M salt of LiPF₆. According to another exemplary embodiment, an electrolyte may be used that uses constituents that may commonly be used in lithium batteries (e.g., propylene carbonate, dimethyl carbonate, vinylene carbonate, lithium bis-oxalatoborate salt (sometimes referred to as LiBOB), etc.). It should be noted that according to an exemplary embodiment, the electrolyte does not include a molten salt.

Various other electrolytes may be used according to other exemplary embodiments. According to an exemplary embodiment, the electrolyte may be a lithium salt dissolved in a polymeric material Such as poly(ethylene oxide) or silicone. According to another exemplary embodiment, the electrolyte may be an ionic liquid such as N-methyl-N-alkylpyrrolidinium bis(trifluoromethanesulfonyl)imide Salts. According to another exemplary embodiment, the electrolyte may be a 3.7 mixture of ethylene carbonate to ethylmethyl carbonate (EC:EMC) in a 1.0 M salt of LiPF₆. According to another exemplary embodiment, the electrolyte may include a polypropylene carbonate solvent and a lithium bis-oxalatoborate salt. According to other exemplary embodiments, the electrolyte may comprise one or more of a PVDF copolymer, a PVDF-polyimide material, and organosilicon polymer, a thermal polymerization gel, a radiation cured acrylate, a particulate with polymer gel, an inorganic gel polymer electrolyte, an inorganic gel-polymer electrolyte, a PVDF gel, poly ethylene oxide (PEO), a glass ceramic electrolyte, phosphate glasses, lithium conducting glasses, and lithium conducting ceramics, among others.

A separator 450 is provided intermediate or between the positive electrode 410 and the negative electrode 420. According to an exemplary embodiment, the separator 450 is a polymeric material Such as a polypropylene/polyethylene copolymer or another polyolefin multilayer laminate that includes micropores formed therein to allow electrolyte lithium ions to flow from one side of the separator to the other.

The positive electrode 410 includes a current collector 412 made of a conductive material such as a metal. According to an exemplary embodiment, the current collector 412 comprises aluminum or an aluminum alloy.

The current collector 412 has a layer of active material 416 provided thereon (e.g., coated on the current collector). While FIG. 4 shows that the active material 416 is provided on only one side of the current collector 412, it should be understood that a layer of active material similar or identical to that shown as active material 416 may be provided or coated on both sides of the current collector 412.

According to an exemplary embodiment, the active material 416 is a material or compound that includes lithium. The lithium included in the active material 416 may be doped and undoped during discharging and charging of the battery, respectively. According to an exemplary embodiment, the active material 416 is lithium cobalt oxide (LiCoO₂). According exemplary embodiments, the active material may be provided as one or more additional materials such as, for example, NCA (LiNi_{0.8}Co_{0.15}Al_{0.05}O₂), NMC111 (LiNi_{0.33}Mn_{0.33}Co_{0.33}O₂), NMC532 (LiNi_{0.5}Mn_{0.3}Co_{0.2}O₂), NMC622 (LiNi_{0.6}Mn_{0.2}Co_{0.2}O₂), NMC811 (LiNi_{0.8}Mn_{0.1}Co_{0.1}O₂), LFP (LiFePO₄), etc.

A binder material may also be utilized in conjunction with the layer of active material 416 to bond or hold the various electrode components together. For example, according to an exemplary embodiment, the layer of active material may include a conductive additive such as carbon black and a binder such as polyvinylidine fluoride (PVDF) or an elastomeric polymer. A ratio of the conductive additive to the binder may be in a range of about 2:3 to about 3:2. In some cases, the ratio of the conductive material to the binder may is about 1:1.

The negative electrode 420 includes a current collector 422 that is made of a conductive material such as a metal. According to an exemplary embodiment, the current collector 422 is aluminum or an aluminum alloy. One advantageous feature of utilizing an aluminum or aluminum alloy current collector is that Such a material is relatively inexpensive and may be relatively easily formed into a current collector. Other advantageous features of using aluminum or an aluminum alloy includes the fact that such materials may have a relatively low density, are relatively highly conductive, are readily weldable, and are generally commercially available. According to another exemplary embodiment, one or both of the positive current collector 412 and the negative current collector 422 is titanium or a titanium alloy.

While the positive current collector 412 and/or the negative current collector 422 has been illustrated and described as being a thin foil material, the positive and/or the negative current collector may have any of a variety of other configurations according to various exemplary embodiments. For example, the one or both of the positive current collector and the negative current collector may be a grid such as a mesh grid, an expanded metal grid, a photochemically etched grid, a metallized polymer film, or the like.

The negative current collector 422 has an active material 424 provided thereon. While FIG. 4 shows that the active material 424 is provided on only one side of the current collector 422, it should be understood that a layer of active material similar or identical to that shown may be provided or coated on both sides of the current collector 422. The active material 424 may include any suitable negative material or materials such as, for example, zirconium dioxide (ZrO₂), titanium dioxide (TiO₂), niobium pentoxide (Nb₂O₅), tungsten trioxide (WO₃), vanadium pentoxide (V₂O₅), lithium titanate (Li₄Ti₅O₁₂), TiNb₂O₇, Ti₂Nb₂O₉, Ti₂Nb₁₀O₂₉, TiNb₆O₁₇, TiNb₁₄O₃₇, TiNb₂₄O₆₂, Nb₁₆W₅O₅₅, and Nb₁₈W₁₆O₉₃, and so on. According to an exemplary embodiment, the active material 424 is lithium titanate (Li₄Ti₅O₁₂). Such active material 424 may provide the battery 400 with an anode (e.g., negative electrode) with a lithium ion intercalation potential of at least 0.5 V over that of lithium metal.

A binder material may also be utilized in conjunction with the layer of active material 424. For example, according to an exemplary embodiment, the layer of active material may include a binder such as polyvinylidine fluoride (PVDF) or an elastomeric polymer. The active material 424 may also include a conductive material Such as carbon (e.g., carbon black).

Recharge burden, especially taking a long time to charge the batteries, may be one of the biggest challenges for the application of rechargeable lithium ion batteries. Typical recharging time can be one to four hours to get full capacity, which may be mainly limited by battery chemistry and battery design. It may be one of big disadvantages of battery powered electrical vehicle vs. conventional vehicle powered by petroleum fuel. Such disadvantages may be an inconvenience for users of portable electronic devices when such devices run out of battery during travel, a conference, and/or during an active communication. Such disadvantages may also be a burden for patients that use rechargeable implantable devices. Rechargeable batteries capable of 5 to 10 minutes recharge to greater than 90% state-of-charge (SOC) may be used to relieve at least some of this burden.

Devices using rechargeable batteries in accordance with embodiments described herein can be used in a variety of applications. For example, the batteries described herein may be used in medical devices such as spinal cord stimulators, neurostimulators, etc. Batteries, systems, and apparatus as described herein may allow such batteries to be charged to full capacity in less than one hour. In some embodiments, the batteries, systems, and apparatus described herein can be used to charge such batteries to greater than 90% state of charge (SOC) within 20 minutes. In some embodiments, the batteries, systems, and apparatus described herein can be used to charge such batteries to greater than 90% state of charge (SOC) within a range of about 5 minutes to 15 minutes.

In general, the lower a batteries resistance, the faster the recharge capability of the battery. Rechargeable Li ion batteries using a LiCoO₂ positive electrode may have a relatively higher energy density than other electrode types and thus extensive used in small portable electronic devices and medical devices. However, a LiCoO₂ electrode may be a dominant factor for battery resistance and stability, especially when negative materials (e.g., ZrO₂, TiO₂, Nb₂O₅, WO₃, V₂O₅, Li₄Ti₅O₁₂, TiNb₂O₇, Ti₂Nb₂O₉, Ti₂Nb₁₀O₂₉, TiNb₆O₁₇, TiNb₁₄O₃₇, TiNb₂₄O₆₂, Nb₁₆W₅O₅₅, or Nb₁₈W₁₆O₉₃, etc.) are used for the negative electrode of the battery.

Embodiments described herein may involve LiCoO₂ electrodes enabling about 10 minutes recharge to greater than 90% SOC. The content of the conductive agent (e.g., carbon) and binder (e.g., PVDF) may be balanced to achieve a super-fast recharge capability (e.g., 10 minutes recharge to greater than 90% SOC). According to various configurations, a ratio of at least two different types of conductive agents may be balanced. For example, a ratio of graphite to carbon black may be balanced to achieve a desired recharge capability. For example, the ratio of graphite (e.g. synthetic graphite) to carbon black may be in a range of about 1:9 to about 9:1. In some cases, the ratio of graphite to carbon black is in a range of about 3:7 to about 7:3.

According to various configurations, the LiCoO₂ content in the positive electrode can have wide range from about 90% to about 98%. In some cases, the LiCoO₂ content is greater than or equal to about 95% to achieve a relatively high energy. With such LiCoO₂ formulation, battery resistance stability is very stable, ensuring stable fast recharge capability of the battery over its service life.

According to various embodiments, a positive electrode is a coating material layer on both sides of the current collector (For example, Al foil and/or Ti foil). In some cases, these is at least a portion of the current collector where only one side is coated or both sides not coated according to specific battery design. The coating material layer may include one or more of active materials, conductive carbon, and/or a binder. For a positive electrode, active material may be a lithium-containing transition metal oxide and/or a mixture of multiple oxides. Conductive carbon may be graphite, carbon black and/or the mixture of both graphite and carbon black. Typical binder materials are polyvinylidene fluoride (PVDF) polymer or carboxymethyl cellulose-styrene-butadiene rubber (CMC-SRB) polymer. A good electrode should have good adhesion to the current collector ensuring not delaminating from the current collector during battery assembly and battery use. According to various configurations a battery with fast recharge capability compared to traditional rechargeable batteries is lower resistance and lower resistance growth rate not impacting the capacity stability overtime. A battery having high energy density and high fast recharge capability may have a positive electrode with high active material percentage in the coating material layer.

Typically, there is a tradeoff between battery energy density and power capability. High power can be achieved by having an electrode contain more conductive carbon. This may lead to less active material in the electrode thus lead to low energy density. To achieve higher energy density, high active material content in the electrode may be used. High active material content leads to not only higher amount of mass but also may lead to higher electrode density if same level of porosity is present in the electrode. This is because active material like LiCoO₂ may have a much higher true density than inner materials like carbon and binder.

Batteries as described herein, may include an anode (e.g., negative electrode) including negative materials (e.g., ZrO₂, TiO₂, Nb₂O₅, WO₃, V₂O₅, Li₄Ti₅O₁₂, TiNb₂O₇, Ti₂Nb₂O₉, Ti₂Nb₁₀O₂₉, TiNb₆O₁₇, TiNb₁₄037, TiNb₂₄O₆₂, Nb₁₆W₅O₅₅, or Nb₁₈W₁₆O₉₃, etc.). Such negative materials may provide a battery that includes a lithium ion intercalation potential of at least 0.5 V above lithium metal. Having an intercalation potential of at least 0.5 V above lithium metal may inhibit or prevent lithium plating during recharge. Accordingly, charging voltage can be increased as the battery ages without significantly increasing the probability of lithium plating.

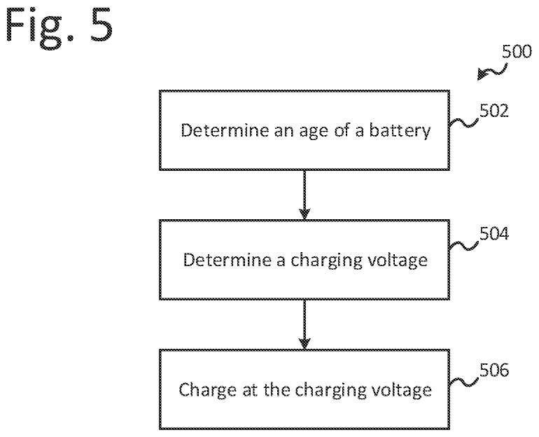

Referring now to FIG. 5, a flow diagram of an embodiment of a process 500 for determining a state of health of an electrochemical is shown.

At 502, an age of a battery (e.g., battery 112 of FIG. 1, battery 310 of FIG. 3, or battery 400 of FIG. 4) is determined. In one embodiment, the age of the battery may be determined based on a number of times the battery has been charged. In one embodiment, the age of the battery may be determined based on a time period between a first charge cycle of the battery and a current charge cycle of the battery.

In one embodiment, determining the age of the battery includes determining an internal impedance of the battery. For example, a test current may be supplied to the battery and a test voltage may be determined while the test current is supplied. The internal impedance of the battery may be determined based on the test voltage and the test current using, for example, Ohm's law, a table of values, etc.

At 504, a charging voltage for charging the battery is determined. The charging voltage for charging the battery may be determined based on the determined age of the battery. The determined charging voltage may increase as the age of the battery increases. In one embodiment, to determine the charging voltage a base charging voltage may be determined, and a charging voltage increase may be determined based on the determined age of the battery. Additionally, the base charging voltage and the charging voltage increase may be summed. Accordingly, the determined charging voltage may be equal to the sum of the determined base charging voltage and the determined charging voltage increase.

In one embodiment, the charging voltage for charging the battery may be based on the determined age of the battery and a charging time threshold. In other words, the determined charging voltage for charging the battery will charge the battery within a time period equal to or less than the charging time threshold. The charging time threshold may be equal to or less than 1 hour, preferably equal to or less than 30 minutes, or more preferably equal to or less than 20 minutes.

In one embodiment, the charging voltage for charging the battery may be determined based on the determined age of the battery and a turbo charge setting. The turbo charge setting may be adjustable by a user. In other words, the charging voltage may be increased to decrease the charging time (e.g., duration) of a charge cycle of the battery below a default charging time.

At 506, the battery is charged at the charging voltage for the duration of a charge cycle. In other words, the battery may be charged using constant voltage charging. The battery may be charged to at least 90% SOC during the charge cycle. The battery may be charged using a charger (e.g., charger 104 of FIG. 1 or charger 210 of FIG. 2).

The invention is defined in the claims. However, below there is provided a non-exhaustive list of non-limiting examples. Any one or more of the features of these examples may be combined with any one or more features of another example, embodiment, or aspect described herein.

Example Ex1: A method comprising:
determining an age of a battery;
determining a charging voltage for charging the battery, wherein the charging voltage increases as the age of the battery increases; and
charging the battery at the charging voltage for the duration of a charge cycle.

Example Ex2: The method of example Ex1, wherein determining the charging voltage comprises:
determining a base charging voltage;
determining a charging voltage increase based on the determined age of the battery; and
summing the base charging voltage and the charging voltage increase.

Example Ex3: The method of example Ex1, wherein determining the age of the battery comprises determining a number of times the battery has been charged.

Example Ex4: The method of example Ex1, wherein determining the age of the battery comprises determining an internal impedance of the battery.

Example Ex5: The method of example Ex1, wherein determining the age of the battery comprises:
supplying a test current to the battery; and
determining a test voltage while the test current is supplied.

Example Ex6: The method of example Ex1, wherein determining the age of the battery comprises determining a time period between a first charge cycle of the battery and a current charge cycle of the battery.

Example Ex7: The method of example Ex1, wherein determining the charging voltage for charging the battery is further based on a charging time threshold.

Example Ex8: The method of example Ex1, wherein determining the charging voltage for charging the battery is further based on a turbo charge setting, wherein the turbo charge setting is adjustable by a user.

Example Ex9: The method of example Ex1, wherein the battery is a lithium ion battery, wherein the battery comprises an anode having a lithium ion intercalation potential of at least 0.5 V above lithium metal.

Example Ex10: A battery charging apparatus comprising:
a charger to charge one or more batteries; and
a computing apparatus comprising one or more processors operably coupled to the charger and configured to:
determine an age of a battery;
determine a charging voltage for charging the battery based on the determined age of the battery, wherein the charging voltage increases as the age of the battery increases; and
cause the charger to charge the battery at the charging voltage for the duration of a charge cycle.

Example Ex11: The apparatus of example Ex10, wherein to determine the charging voltage the computing apparatus is configured to:
determine a base charging voltage;
determine a charging voltage increase based on the determined age of the battery; and
sum the base charging voltage and the charging voltage increase.

Example Ex12: The apparatus of example Ex10, wherein to determine the age of the battery, the computing apparatus is configured to determine a number of times the battery has been charged.

Example Ex13: The apparatus of example Ex10, wherein to determine the age of the battery, the computing apparatus is configured to determine an internal impedance of the battery.

Example Ex14: The apparatus of example Ex10, wherein to determine the age of the battery, the computing apparatus is configured to:
supply a test voltage to the battery; and
determine a test current while the test voltage is supplied.

Example Ex15: The apparatus of example Ex10, wherein to determine the age of the battery, the computing apparatus is configured to determine a time period between a first charge cycle of the battery and a current charge cycle of the battery.

Example Ex16: The apparatus of example Ex10, wherein the computing apparatus is configured to determine the charging voltage based on the determined age of the battery and a charging time threshold.

Example Ex17: The apparatus of example Ex10, wherein the computing apparatus is configured to determine the charging voltage based on the determined age of the battery and a turbo charge setting, wherein the turbo charge setting is adjustable by a user.

Example Ex18: The apparatus of example Ex10, wherein the battery is a lithium ion battery, wherein the battery comprises an anode having a lithium ion intercalation potential of at least 0.5 V above lithium metal.

Example Ex19: A system comprising:
a charging apparatus for charging one or more batteries; and
a battery operatively coupled to the charging apparatus, the battery comprising:
one or more electrochemical cells; and
a battery management system comprising one or more processors operably coupled to the one or more electrochemical cells and configured to:
determine an age of the battery;
determine a charging voltage for charging the battery based on the determined age of the battery, wherein the charging voltage increases as the age of the battery increases; and
cause the charger to charge the battery at the charging voltage for the duration of a charge cycle.

Example Ex20: The system of example Ex19, wherein to determine the charging voltage, the battery management system is configured to:
determine a base charging voltage;
determine a charging voltage increase based on the determined age of the battery; and
sum the base charging voltage and the charging voltage increase.

Example Ex21: The system of example Ex19, wherein to determine the age of the battery, the battery management system is configured to determine a number of times the battery has been charged.

Example Ex22: The system of example Ex19, wherein to determine the age of the battery, the battery management system is configured to determine an internal impedance of the battery.

Example Ex23: The system of example Ex19, wherein to determine the age of the battery, the battery management system is configured to:
supply a test current to the battery; and
determine a test voltage while the test current is supplied.

Example Ex24: The system of example Ex19, wherein to determine the age of the battery, the battery management system is configured to determine a time period between a first charge cycle of the battery and a current charge cycle of the battery.

Example Ex25: The system of example Ex19, wherein the battery is disposed in a device.

Example Ex26: The system of example Ex19, wherein the battery is a lithium ion battery, wherein the battery comprises an anode having a lithium ion intercalation potential of at least 0.5 V above lithium metal.

All scientific and technical terms used herein have meanings commonly used in the art unless otherwise specified. The definitions provided herein are to facilitate understanding of certain terms used frequently herein and are not meant to limit the scope of the present disclosure.

As used herein, singular forms “a,” “an” and “the” include plural referents unless the context clearly dictates otherwise. As used in this specification and the appended claims, the term “or” is generally employed in its sense including “and/or” unless the content clearly dictates otherwise. The term “and/or” means one or all of the listed elements or a combination of any two or more of the listed elements.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the inventive technology.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be apparent to those skilled in the art that various modifications and variations can be made to the present inventive technology without departing from the spirit and scope of the disclosure. Since modifications, combinations, sub-combinations and variations of the disclosed embodiments incorporating the spirit and substance of the inventive technology may occur to persons skilled in the art, the inventive technology should be construed to include everything within the scope of the appended claims and their equivalents.

What is claimed is:

1. A method comprising:
determining an age of a battery;
determining a charging voltage for charging the battery, wherein the charging voltage increases as the age of the battery increases; and
charging the battery at the charging voltage for the duration of a charge cycle.

2. The method of claim 1, wherein determining the charging voltage comprises:
determining a base charging voltage;
determining a charging voltage increase based on the determined age of the battery; and
summing the base charging voltage and the charging voltage increase.

3. The method of claim 1, wherein determining the age of the battery comprises determining a number of times the battery has been charged.

4. The method of claim 1, wherein determining the age of the battery comprises determining an internal impedance of the battery.

5. The method of claim 1, wherein determining the age of the battery comprises:
supplying a test current to the battery; and
determining a test voltage while the test current is supplied.

6. The method of claim 1, wherein determining the age of the battery comprises determining a time period between a first charge cycle of the battery and a current charge cycle of the battery.

7. The method of claim 1, wherein determining the charging voltage for charging the battery is further based on a charging time threshold.

8. The method of claim 1, wherein determining the charging voltage for charging the battery is further based on a turbo charge setting, wherein the turbo charge setting is adjustable by a user.

9. The method of claim 1, wherein the battery is a lithium ion battery, wherein the battery comprises an anode having a lithium ion intercalation potential of at least 0.5 V above lithium metal.

10. A battery charging apparatus comprising:
a charger to charge one or more batteries; and
a computing apparatus comprising one or more processors operably coupled to the charger and configured to:
determine an age of a battery;
determine a charging voltage for charging the battery based on the determined age of the battery, wherein the charging voltage increases as the age of the battery increases; and
cause the charger to charge the battery at the charging voltage for the duration of a charge cycle.

11. The apparatus of claim 10, wherein to determine the charging voltage the computing apparatus is configured to:
determine a base charging voltage;
determine a charging voltage increase based on the determined age of the battery; and
sum the base charging voltage and the charging voltage increase.

12. The apparatus of claim 10, wherein to determine the age of the battery, the computing apparatus is configured to determine a number of times the battery has been charged.

13. The apparatus of claim 10, wherein to determine the age of the battery, the computing apparatus is configured to determine an internal impedance of the battery.

14. The apparatus of claim 10, wherein to determine the age of the battery, the computing apparatus is configured to:
supply a test voltage to the battery; and
determine a test current while the test voltage is supplied.

15. The apparatus of claim 10, wherein to determine the age of the battery, the computing apparatus is configured to determine a time period between a first charge cycle of the battery and a current charge cycle of the battery.

16. The apparatus of claim 10, wherein the computing apparatus is configured to determine the charging voltage based on the determined age of the battery and a charging time threshold.

17. The apparatus of claim 10, wherein the computing apparatus is configured to determine the charging voltage based on the determined age of the battery and a turbo charge setting, wherein the turbo charge setting is adjustable by a user.

18. The apparatus of claim 10, wherein the battery is a lithium ion battery, wherein the battery comprises an anode having a lithium ion intercalation potential of at least 0.5 V above lithium metal.

19. A system comprising:
a charging apparatus for charging one or more batteries; and
a battery operatively coupled to the charging apparatus, the battery comprising:
one or more electrochemical cells; and
a battery management system comprising one or more processors operably coupled to the one or more electrochemical cells and configured to:
determine an age of the battery;
determine a charging voltage for charging the battery based on the determined age of the battery, wherein the charging voltage increases as the age of the battery increases; and
cause the charger to charge the battery at the charging voltage for the duration of a charge cycle.

20. The system of claim 19, wherein to determine the charging voltage, the battery management system is configured to:
determine a base charging voltage;
determine a charging voltage increase based on the determined age of the battery; and
sum the base charging voltage and the charging voltage increase.

21. The system of claim 19, wherein to determine the age of the battery, the battery management system is configured to determine a number of times the battery has been charged.

22. The system of claim 19, wherein to determine the age of the battery, the battery management system is configured to determine an internal impedance of the battery.

23. The system of claim 19, wherein to determine the age of the battery, the battery management system is configured to:
supply a test current to the battery; and
determine a test voltage while the test current is supplied.

24. The system of claim 19, wherein to determine the age of the battery, the battery management system is configured to determine a time period between a first charge cycle of the battery and a current charge cycle of the battery.

25. The system of claim 19, wherein the battery is disposed in a device.

26. The system of claim 19, wherein the battery is a lithium ion battery, wherein the battery comprises an anode having a lithium ion intercalation potential of at least 0.5 V above lithium metal.
